(19) United States
(12) Patent Application Publication
(10) Pub. No.: US 2023/0160084 A1
(43) Pub. Date: May 25, 2023

(54) Method for Improving Pit Defect Formed After Copper Electroplating Process

(71) Applicant: Shanghai Huali Integrated Circuit Corporation, Shanghai (CN)

(72) Inventors: Bo Liu, Shanghai (CN); Jingshan Huang, Shanghai (CN); Zhengyan Chen, Shanghai (CN)

(73) Assignee: Shanghai Huali Integrated Circuit Corporation, Shanghai (CN)

(21) Appl. No.: 17/870,976

(22) Filed: Jul. 22, 2022

(30) Foreign Application Priority Data
Nov. 25, 2021 (CN) 202111409294.X

(51) Int. Cl. C25D 3/38; C25D 5/54; C25D 5/00; C25D 7/12; C23F 1/02; C23C 16/02; C23C 28/00; H01L 21/321

(52) U.S. Cl. CPC C25D 3/38; C25D 5/54; C25D 5/611; C25D 7/123; C23F 1/02; C23C 16/0227; C23C 28/34; H01L 21/3212

(57) ABSTRACT

The present application provides a method for improving a pit defect formed after a copper electroplating process, comprising: forming a dielectric layer on a wafer; etching the dielectric layer to form a trench; forming a seed barrier layer on the surface of the trench; pre-cleaning the wafer to increase the wetness of the trench on the wafer; filling the trench with copper by means of electroplating; polishing the upper surface of the trench to planarize the upper surface of the trench. The wetness of the wafer surface can be increased by pre-cleaning a via. An excessively dry wafer surface leads to a poor wetness effect when the wafer enters water, a bubble is difficult to be discharged, a void is easy to be generated in electroplating. By the pre-cleaning step, the problem of a poor wetness effect occurring when the wafer enters water can be effectively improved.

### CROSS REFERENCE TO RELATED APPLICATIONS

This application claims priority to Chinese Patent Application No. 202111409294.X, filed on Nov. 25, 2021, the disclosure of which is incorporated herein by reference in its entirety.

### TECHNICAL FIELD

The present application relates to the technical field of semiconductors, in particular to a method for improving a pit defect formed after a copper electroplating process.

### BACKGROUND

As the size of metal copper wires shrinks, the opening of a metal via becomes increasingly small, and the gap filling of copper electroplating becomes more difficult. An XCDA purified environment protects a seed layer and improves a gap filling window while rendering the surface of a wafer excessively dry, resulting in a poor electroplating wetness effect. A bubble generated when the excessively dry wafer enters water is difficult to be discharged, and a surface void is formed in electroplating, thereby forming a pit defect in a subsequent CMP process. Therefore, it is necessary to optimize the electroplating method to solve the problem of the defect formed after the CMP in the XCDA purified environment.

### BRIEF SUMMARY

In view of the above defect in the prior art, the objective of the present application is to provide a method for improving a pit defect formed after a copper electroplating process, so as to solve the problem of a defect formed after metal via filling in the prior art.

In order to achieve the above objective and other related objectives, the present application provides a method for improving a pit defect formed after a copper electroplating process, at least including:

step 1, providing a wafer, and forming a dielectric layer on the wafer;

step 2, etching the dielectric layer to form a trench;

step 3, sequentially forming a seed barrier layer and a conductive layer on the surface of the trench;

step 4, pre-cleaning the wafer to increase the wetness of the trench on the wafer;

step 5, filling the trench with copper by means of electroplating; and

step 6, polishing the upper surface of the trench to planarize the upper surface of the trench.

In some examples, in step 2, the trench is first defined by means of photolithography, and then the dielectric layer is etched to form the trench.

In some examples, the formation of the barrier layer and the conductive layer in step 3 is achieved by means of a PVD process.

In some examples, the wafer is pre-cleaned with deionized water in step 4.

In some examples, a method of pre-cleaning the wafer in step 4 is as follows: the wafer is enabled to rotate at 2-20 rpm/s, a chuck is provided, and nozzles are provided every 60 degrees on the edge of the chuck, the nozzles spraying deionized water toward the center of the wafer in a scattered manner.

In some examples, the flow rate of the deionized water in step 4 is 2 L/min, and a spray time is 3-10 s.

In some examples, a method for filling the trench with copper by means of electroplating in step 5 is as follows: the wafer is inclined by about 3 degrees with the frontside thereof facing downward, and is rotated into an electroplating solution so as to be electroplated.

In some examples, in step 6, the upper surface of the trench is polished by means of a chemical mechanical polishing method so as to be planarized.

As stated above, the method for improving a pit defect formed after a copper electroplating process of the present application has the following beneficial effects: in the present application, the wetness of the wafer surface can be increased by pre-cleaning a via. During copper electroplating filling, an excessively dry wafer surface leads to a poor wetness effect when the wafer enters water, a bubble is difficult to be discharged, and a void is easy to be generated in electroplating. By adding the pre-cleaning step, the problem of a poor wetness effect occurring when the wafer enters water can be effectively improved, thereby improving the gap filling capability and preventing the occurrence of a defect.

### BRIEF DESCRIPTION OF THE DRAWINGS

FIG. 1 is a flowchart of a method for improving a pit defect formed after a copper electroplating process in the present application.

FIG. 2 is a schematic structural diagram showing a dielectric layer provided with a trench and a seed barrier layer and partially electroplated with copper in the present application.

FIG. 3 is a schematic diagram of trench pre-cleaning in the present application.

FIG. 4 is a schematic structural diagram showing the trench electroplated with copper in the present application.

### DETAILED DESCRIPTION OF THE DISCLOSURE

The embodiments of the present application are described below using specific examples, and those skilled in the art can easily understand other advantages and effects of the present application from the contents disclosed in the Description. The present application can also be implemented or applied using other different specific embodiments, and various details in the Description can also be modified or changed based on different viewpoints and applications without departing from the spirit of the present application.

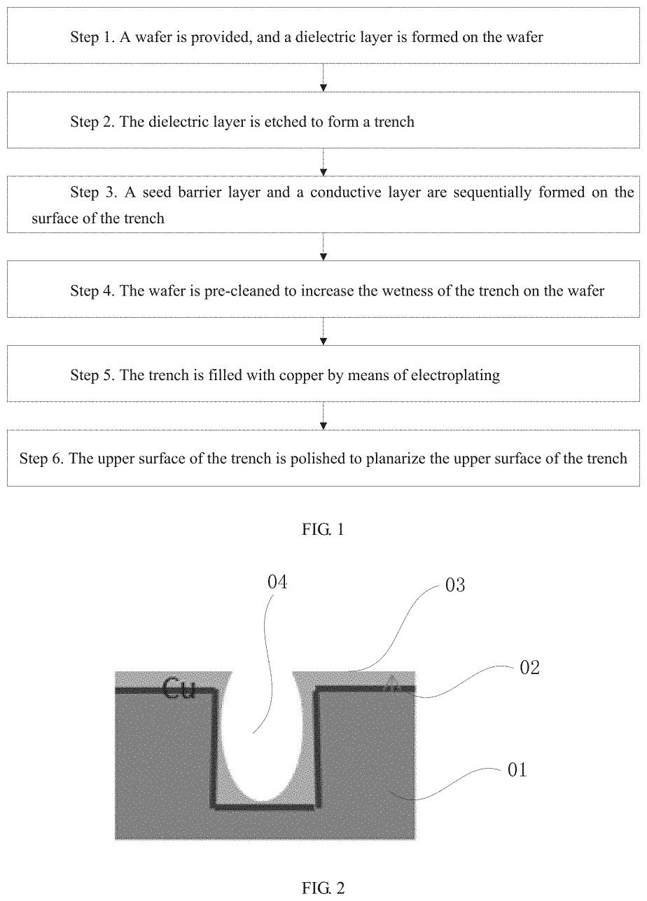

Please refer to FIGS. 1-4. It should be noted that the drawings provided in this embodiment are only used to illustrate the basic concept of the present application in a schematic way, so the drawings only show the components related to the present application rather than being drawn according to the number, shape, and size of the components in actual implementation. The type, number, and proportion of various components can be changed randomly during actual implementation, and the layout of components may be more complicated.

The present application provides a method for improving a pit defect formed after a copper electroplating process. Referring to FIG. 1, FIG. 1 is a flowchart of the method for improving a pit defect formed after a copper electroplating process in the present application. The method at least includes the following steps.

Step 1. A wafer is provided, and a dielectric layer is formed on the wafer. Referring to FIG. 2, FIG. 2 is a schematic structural diagram showing the dielectric layer provided with a trench and a seed barrier layer and partially electroplated with copper in the present application. In step 1, the dielectric layer 01 is first formed on the wafer, and the dielectric layer formed in step 1 is not etched.

Step 2. The dielectric layer is etched to form a trench. Referring to FIG. 2, in step 2, the dielectric layer 01 is etched to form the trench 04.

In this embodiment of the present application, in step 2, the trench is first defined by means of photolithography, and then the dielectric layer is etched to form the trench. That is, in step 2, a photoresist pattern is first formed on the dielectric layer by means of photolithography, and then the dielectric layer is etched according to the photoresist pattern to form the trench 04 as shown in FIG. 2.

Step 3. A seed barrier layer and a conductive layer are formed on the surface of the trench. Referring to FIG. 2, in step 3, the seed barrier layer 02 and the conductive layer 03 are formed on the surface of the trench 04, wherein the seed barrier layer covers the bottom and sidewall of the inside of the trench and upper surfaces of two sides of the trench.

In this embodiment of the present application, the formation of the barrier layer and the conductive layer in step 3 is achieved by means of a PVD process.

Step 4. The wafer is pre-cleaned to increase the wetness of the trench on the wafer. The wafer is cleaned in step 4. Before cleaning, the inside of the trench on the wafer is relatively dry, and after the cleaning, the wetness of the inside of the trench can be increased.

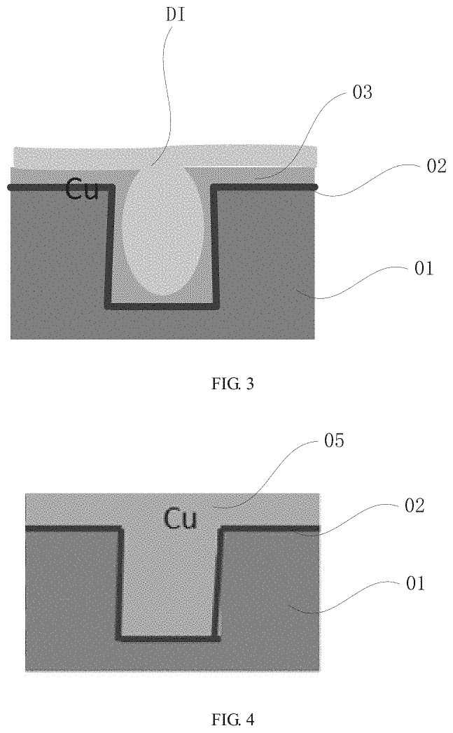

In this embodiment of the present application, the wafer is pre-cleaned with deionized water (DI water) in step 4 to increase the wetness of the trench. Referring to FIG. 3, FIG. 3 is a schematic diagram of trench pre-cleaning in the present application.

In this embodiment of the present application, a method of pre-cleaning the wafer in step 4 is as follows: the wafer is enabled to rotate at 2-20 rpm/s, a chuck is provided, and nozzles are provided every 60 degrees on the edge of the chuck, the nozzles spraying deionized water toward the center of the wafer in a scattered manner.

In this embodiment of the present application, the flow rate of the deionized water in step 4 is 2 L/min, and a spray time is 3-10 s.

Step 5. The trench is filled with copper by means of electroplating. Referring to FIG. 4, FIG. 4 is a schematic structural diagram showing the trench electroplated with copper in the present application. FIG. 4 shows a fully electroplated structure. In step 5, the trench 04 is filled with copper 05 by means of an electroplating process.

In this embodiment of the present application, a method for filling the trench with copper by means of electroplating in step 5 is as follows: the wafer is inclined by about 3 degrees with the frontside thereof facing downward, and is rotated into an electroplating solution so as to be electroplated. After the electroplating filling, the trench is fully covered with copper, and the upper surfaces of the two sides outside the trench are also covered with copper.

Step 6. The upper surface of the trench is polished to planarize the upper surface of the trench.

In this embodiment of the present application, in step 6, the upper surface of the trench is polished by means of a chemical mechanical polishing method so as to be planarized.

To sum up, in the present application, the wetness of the wafer surface can be increased by pre-cleaning a via. During copper electroplating filling, an excessively dry wafer surface leads to a poor wetness effect when the wafer enters water, a bubble is difficult to be discharged, and a void is easy to be generated in electroplating. By adding the pre-cleaning step, the problem of a poor wetness effect occurring when the wafer enters water can be effectively improved, thereby improving the gap filling capability and preventing the occurrence of a defect. Therefore, the present application effectively overcomes various defects in the prior art and has high industrial utilization value.

The above embodiment merely illustrates the principle and effect of the present application, rather than limiting the present application. Anyone skilled in the art can modify or change the above embodiment without departing from the spirit and scope of the present application. Therefore, all equivalent modifications or changes made by those with ordinary knowledge in the art without departing from the spirit and technical idea disclosed in the present application shall still be covered by the claims of the present application.

What is claimed is:

1. A method for improving a pit defect formed after a copper electroplating process, at least comprising:
step 1, providing a wafer, and forming a dielectric layer on the wafer;
step 2, etching the dielectric layer to form a trench;
step 3, sequentially forming a seed barrier layer and a conductive layer on a surface of the trench;
step 4, pre-cleaning the wafer to increase a wetness of the trench;
step 5, filling the trench with copper by means of electroplating; and
step 6, polishing an upper surface of the trench to planarize the upper surface of the trench.

2. The method for improving the pit defect formed after the copper electroplating process according to claim 1, wherein in step 2, the trench is first defined by means of photolithography, and then the dielectric layer is etched to form the trench.

3. The method for improving the pit defect formed after the copper electroplating process according to claim 1, wherein the forming the seed barrier layer and the conductive layer is achieved by means of a PVD process.

4. The method for improving the pit defect formed after the copper electroplating process according to claim 1, wherein the pre-cleaning the wafer comprises precleaning with deionized water.

5. The method for improving the pit defect formed after the copper electroplating process according to claim 1, wherein the pre-cleaning the wafer comprises:
enabling the wafer to rotate at 2-20 rpm/s;
providing a chuck, wherein nozzles are provided every 60 degrees on an edge of the chuck; and
spraying, via the nozzles, deionized water toward a center of the wafer in a scattered manner.

6. The method for improving the pit defect formed after the copper electroplating process according to claim 5, wherein a flow rate of the deionized water is 2 L/min, and a spray time is 3-10 s.

7. The method for improving the pit defect formed after the copper electroplating process according to claim 4, wherein the filling the trench with copper by means of electroplating comprises:
inclining the wafer by about 3 degrees with a frontside thereof facing downward; and
rotating the wafer into an electroplating solution so as to be electroplated.

8. The method for improving the pit defect formed after the copper electroplating process according to claim 1, wherein the polishing the upper surface of the trench comprises polishing by means of a chemical mechanical polishing method so as to be planarized.
